(19) United States
(12) Patent Application Publication
(10) Pub. No.: US 2004/0188720 A1
(43) Pub. Date: Sep. 30, 2004

(54) Bit-cell and method for programming

(76) Inventor: Kenneth S. Chew, Granite Bay, CA (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/400,144

(22) Filed: Mar. 25, 2003

(51) Int. Cl. G11C 7/00; H01L 27/10

(52) U.S. Cl. 257/211; 257/209; 257/208; 365/189.12

(57) ABSTRACT

A bit-cell includes a plurality of bridge structures and a driver including an input port and an output port. The input port is connected to each of the plurality of bridge structures and at most one of the plurality of bridge structures is connected to a signal source. A method includes removing a conductive element in a first particular conductive layer from a first bridge structure and adding a conductive element in the first particular conductive layer to connect a second bridge structure to a first signal source.

### FIELD

This invention relates to integrated circuits and, more particularly, to bit-cells used in integrated circuits.

### BACKGROUND

The bit-cells used in revision identification registers to identify a revision level of an integrated circuit are often synthesized, placed, and routed using automated tools. Often, multiple metal layers must be modified to implement these automatically generated revision identification registers. It is usually not possible to confine the modifications of the bit-cells in automatically generated revision identification registers to a single metal layer. Hence, even if a logic change to an integrated circuit only requires modification of a single metal layer, the corresponding changes to the revision identification registers may require changing more than one metal layer, which increases the cost of the change.

### BRIEF DESCRIPTION OF THE DRAWINGS

FIG. 1A is an illustration of bit-cell including a plurality of bridge structures in accordance with some embodiments of the present invention.

FIG. 1B is an illustration of one of the plurality of bridge structures shown in FIG. 1A in accordance with some embodiments of the present invention.

FIG. 1C is a cross-sectional view, taken along the section line X, of the conductive stack, shown in FIG. 1B, illustrating the relationship between the coupling structure and two adjacent conductive elements in accordance with some embodiments of the present invention.

FIG. 1D is an illustration of the bridge structure, shown in FIG. 1B, in which the conductive stack, shown in FIG. 1B, is replaced with a conductive stack that has a gap in accordance with some embodiments of the present invention.

FIG. 1E is an illustration of a conductive stack and a conductive element that connect a signal source to the bridge structure shown in FIG. 1A in accordance with some embodiments of the present invention.

FIG. 1F is a schematic diagram of the driver shown in FIG. 1A in accordance with some embodiments of the present invention.

FIG. 2 is a block diagram of a communication system including a plurality of bit-cells shown in FIG. 1A in accordance some embodiments of the present invention.

FIG. 3 is an illustration of an interconnect including a first conductive bridge structure and a second conductive bridge structure, such as the conductive bridge structure shown in FIG. 1B, in accordance with some embodiments of the present invention.

FIG. 4 is flow diagram of a method for modifying the bit-cell shown in FIG. 1A in accordance with some embodiments of the present invention.

FIG. 5 is a block diagram of a computer system including a processor and a die including an identification register, shown in FIG. 2, having a plurality of conductive bridge structures, shown in FIG. 1B.

FIG. 6 is a block diagram of an apparatus including an information storage structure including one or more bit-cells, shown in FIG. 1A, and logic formed on a substrate in accordance with some embodiments of the present invention.

### DESCRIPTION

In the following description of some embodiments of the present invention, reference is made to the accompanying drawings which form a part hereof, and in which are shown, by way of illustration, specific embodiments of the present invention which may be practiced. In the drawings, like numerals describe substantially similar components throughout the several views. These embodiments are described in sufficient detail to enable those skilled in the art to practice the present invention. Other embodiments may be utilized and structural, logical, and electrical changes may be made without departing from the scope of the present invention. The following detailed description is not to be taken in a limiting sense, and the scope of the present invention is defined only by the appended claims, along with the full scope of equivalents to which such claims are entitled.

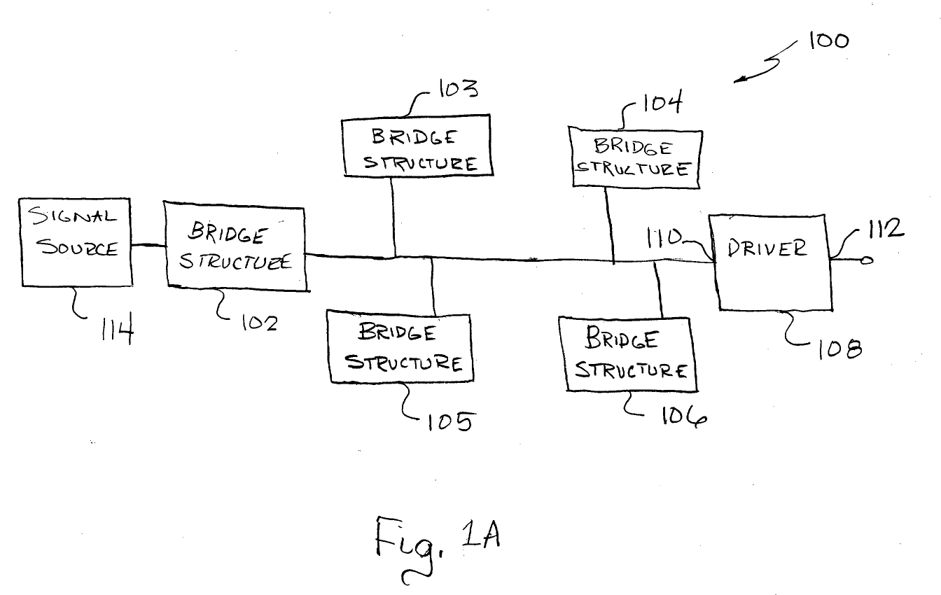

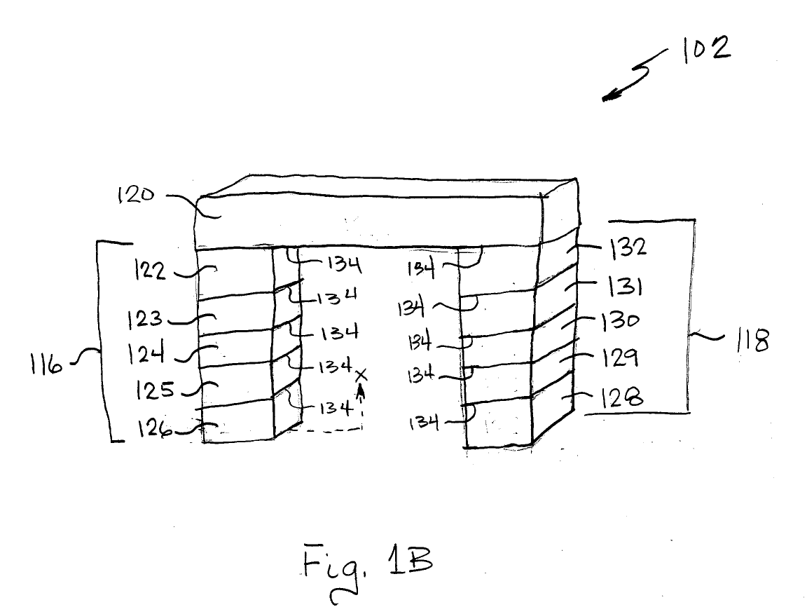

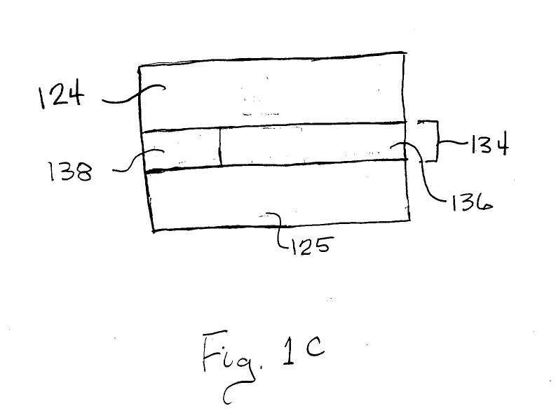

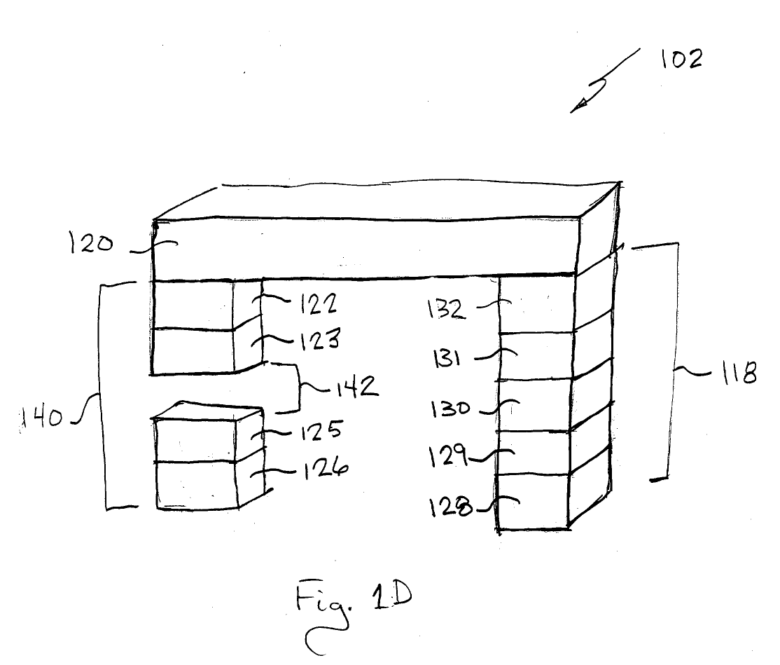

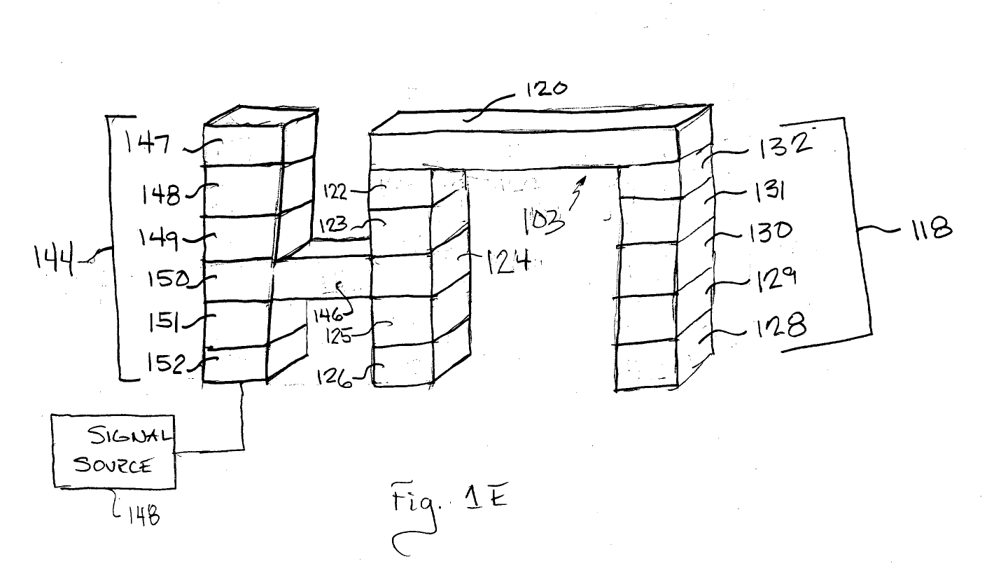

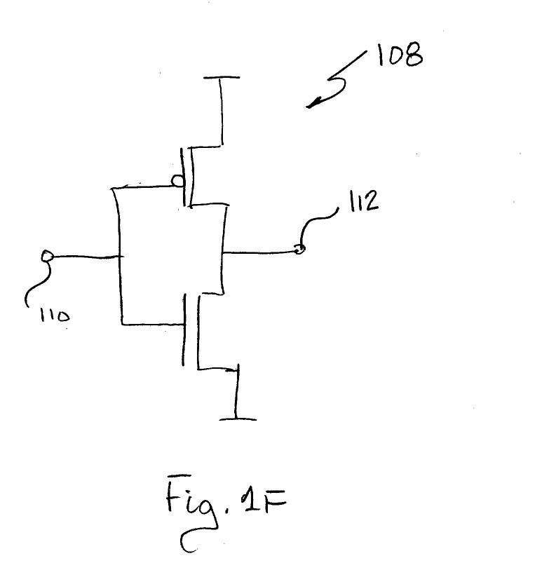

FIG. 1A is an illustration of a bit-cell 100 including a plurality of bridge structures 102, 103, 104, 105, and 106 in accordance with some embodiments of the present invention. In addition to the plurality of bridge structures 102, 103, 104, 105, and 106, the bit-cell 100 includes a driver 108 having an input port 110 and an output port 112, and a signal source 114. The signal source 114 is connected to the bridge structure 102. Each of the plurality of bridge structures 102, 103, 104, 105, and 106 is connected to the input port 110 of the driver 108.

In operation, the signal source 114 provides a signal to the bridge structure 102. The bridge structure 102 provides a conductive path between the signal source 114 and the input port 110 of the driver 108. The driver 108 processes the signal and provides a processed signal at the output port 112. The bridge structures 103, 104, 105, and 106 are not connected to a signal source, so the bridge structures 103, 104, 105, and 106 do not provide a signal to the input port 110 of the driver 108. If the signal source 114 is disconnected from the bridge structure 102, then a signal source (not shown) can be connected to one of the bridge structures 103, 104, 105, or 106 to provide a signal to the driver 108.

FIG. 1B is an illustration of one of the plurality of bridge structures 102, 103, 104, 105, and 106 shown in FIG. 1A in accordance with some embodiments of the present invention. The bridge structure 102 includes conductive stacks 116 and 118. The conductive stack 116 is connected to the conductive stack 118 by a conductive beam 120.

The conductive stack 116 includes a plurality of conductive elements 122, 123, 124, 125, and 126. The conductive stack 118 includes a plurality of conductive elements 128, 129, 130, 131, and 132. Each of the conductive elements 122, 123, 124, 125, and 126, and each of the conductive elements 128, 129, 130, 131, and 132 are connected to adjacent conductive elements or to the conductive beam 120 by a coupling structure 134.

FIG. 1C is a cross-sectional view, taken along the section line X, of the conductive stack 116, shown in FIG. 1B, illustrating the relationship between the coupling structure 134 and two adjacent conductive elements 124 and 125 in accordance with some embodiments of the present invention. The coupling structure 134 includes a dielectric 136 and a via 138. As can be seen in FIG. 1C, the via 138 is not centered within the coupling structure 134. Rather, the via 138 is located on one side of the coupling structure 134, and the dielectric 136 is located on the other side. The via 138 and the dielectric 136 swap sides in an adjacent coupling structure 134. The dielectric 136 is a non-conductor of electronic charge. In some embodiments, the dielectric 136 is silicon dioxide. The via 138 is a conductor of electronic charge. In some embodiments the via is a metal. Exemplary metals suitable for use in connection with the fabrication of the via 138 include aluminum, copper, tungsten, and alloys of aluminum, copper, and tungsten. In some embodiments, the via is polysilicon.

Referring again to FIG. 1B, the conductive beam 120, each of the plurality of conductive elements 122, 123, 124, 125, and 126, and each of the plurality of conductive elements 128, 129, 130, 131, and 132 are formed from a conductive material. In some embodiments, the conductive beam 120, each of the plurality of conductive elements 122, 123, 124, 125, and 126, and each of the plurality of conductive elements 128, 129, 130, 131, and 132 is formed from a metal. Exemplary metals suitable for use in connection with the fabrication of the conductive beam 120, the plurality of conductive elements 122, 123, 124, 125, and 126, and each of the plurality of conductive elements 128, 129, 130, 131, and 132 include aluminum, tungsten, and copper and alloys of aluminum, tungsten, and copper. Each of the plurality of conductive elements 122, 123, 124, 125, and 126 and each of the plurality of conductive elements 128, 129, 130, 131, and 132 is connected to one or more adjacent elements. The conductive beam 120 is connected to conductive elements 122 and 132.

FIG. 1D is an illustration of the bridge structure 102, shown in FIG. 1B, in which the conductive stack 116, shown in FIG. 1B, is replaced with a conductive stack 140 that has a gap 142 in accordance with some embodiments of the present invention. The bridge structure 102 shown in FIG. 1D includes the conductive stack 118, the conductive beam 120, and the conductive stack 140. The conductive beam 120 connects the conductive stack 140 to the conductive stack 118.

The conductive stack 140 includes the conductive elements 122, 123, 125, and 126 included in the conductive stack 116, shown in FIG. 1B, however, the conductive stack 140 does not include the conductive element 124 included in the conductive stack 116. The conductive stack 140 includes the gap 142 in place of the conductive element 124 (shown in FIG. 1B) of the conductive stack 116. In some embodiments, the bridge structure 102 is formed using a six-layer metallization process. The conductive element 126, in a six-layer metallization process, is included in the first metallization layer and the conductive beam 120 is included in the sixth metallization layer. Each metallization layer in a six-layer metallization process is defined by a mask. The gap 142 is included on metallization layer three and the mask used to define the conductive element 124 is modified to define the gap 142 in the conductive stack 140.

FIG. 1E is an illustration of a conductive stack 144 and a conductive element 146 that connect a signal source 148 to the bridge structure 103, shown in FIG. 1A, in accordance with some embodiments of the present invention. The conductive stack 144 includes a plurality of conductive elements 147, 148, 149, 150, 151, and 152. The materials and methods used in the fabrication of the conductive stacks 116 and 118 shown in FIG. 1B and described above are suitable for use in connection with the fabrication of the conductive stack 144. The materials and methods used in the fabrication of the plurality of conductive elements 122, 123, 124, 125, and 126 shown in FIG. 1B and described above are suitable for use in connection with the fabrication of the plurality of conductive elements 147, 148, 149, 150, 151, and 152.

The conductive element 146 connects the conductive stack 144 to the bridge structure 102. The materials and methods used in the fabrication of the plurality of conductive elements 122, 123, 124, 125, and 126 (shown in FIG. 1B) and described above are suitable for use in connection with the fabrication of the conductive element 146. The conductive element 146 is formed on the third metallization layer and connects the conductive element 150 of the conductive stack 144 to the conductive element 124 of the conductive stack 116 in the bridge structure 103. The conductive element 146 is defined in the metallization layer three mask.

FIG. 1F is a schematic diagram of the driver 108 shown in FIG. 1A in accordance with some embodiments of the present invention. The driver 108 is not limited to a particular type of circuit, a particular technology, or a particular power level. The driver 108 is an inverter having the input port 110 and the output port 112. Technologies suitable for use in the fabrication of the driver 108 includes semiconductor technologies, such as silicon, germanium, and gallium arsenide. The driver 108 is not limited to processing a particular type of signal. Exemplary types of signals suitable for processing by the driver 108 include logic signals, such as digital signals, and power signals, such as power source signals.

Referring again to FIGS. 1A, 1B, 1D, and 1E, in the bit-cell 100 a change to a particular layer (the third metallization layer in this embodiment) can change the signal provided at the output port 112 of the driver 108. The change can be accomplished by editing only a single mask. The change includes removing the conductive element 124 from the conductive bridge 102 (thereby disconnecting the signal source 114 from the driver 108) and adding the conductive element 146 between the conductive stack 144 and the conductive bridge 103 (thereby connecting the signal source 148 to the driver 108). Thus, if changing only a single mask level is sufficient to update an integrated circuit, then a change to the bit-cell 100 on the same mask level is sufficient to update the revision level (represented by the bit-cell 100) of the integrated circuit.

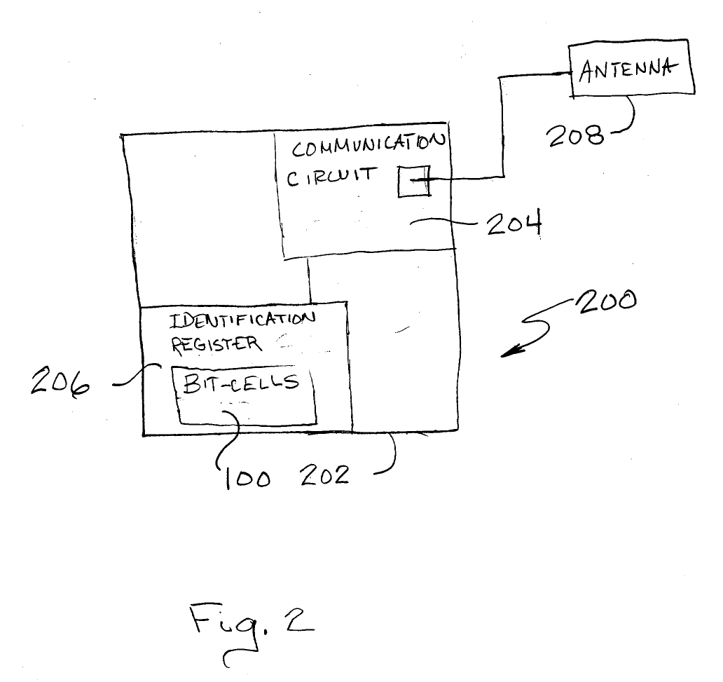

FIG. 2 is a block diagram of a communication system 200 including a plurality of bit-cells 100 shown in FIG. 1A in accordance some embodiments of the present invention. The communication system 200 includes a substrate 202, a communication circuit 204, and an identification register 206. The communication circuit 204 and the identification register 206 are formed on the substrate 202. The communication circuit 204 is coupled to an antenna 208. The identification register 206 includes the plurality of bit-cells 100. Each of the plurality of bit-cells 100 can be changed during manufacturing of the communication circuit 204 by changing only one metallization mask. The plurality of bit-cells 100 includes a plurality of bridge structures 102, 103, 104, 105, and 106 (shown in FIG. 1A) formed on the substrate 202. The bridge structures 102, 103, 104, 105, and 106 are formed from the metallization layers included in the fabrication of the communication circuit 204. The substrate 202 is not limited to a particular material. Exemplary substrate 202 materials suitable for use in connection with the fabrication of the communication circuit 204 include semiconductors, such as silicon, germanium, and gallium arsenide.

In operation, the identification register 206 can provide version information to the communication circuit 204. The communication circuit 204 is coupled to the antenna 208 to transmit and receive information.

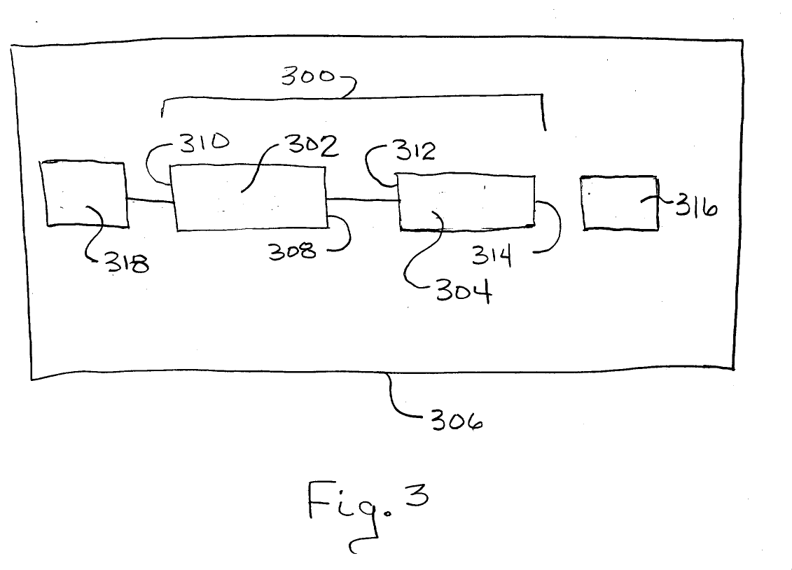

FIG. 3 is an illustration of an interconnect 300 including a first conductive bridge structure 302 and a second conductive bridge structure and 304, such as the conductive bridge structure 102, shown in FIG. 1B, in accordance with some embodiments of the present invention. The first and second conductive bridge structures 302 and 304 are formed on a substrate 306. The first conductive bridge structure 302 includes a proximal end 308 and a distal end 310. The second conductive bridge structure 304 includes a proximal end 312 and a distal end 314. The proximal end 308 of the first conductive bridge structure 302 is connected to the proximal end 312 of the second conductive bridge structure 304. The distal end 310 of the first conductive bridge structure 302 and the distal end 314 of the second conductive bridge structure 304 are unconnected. In some embodiments, the distal end 314 of the second conductive bridge structure 304 is adjacent to a first power source contact 316. In some embodiments, a signal source 318, such as a logical signal source, is connected to the distal end 310 of the first bridge structure 302. In some embodiments, the first power source contact 316 comprises a conductive stack, such as the conductive stack 144 shown in FIG. 1E.

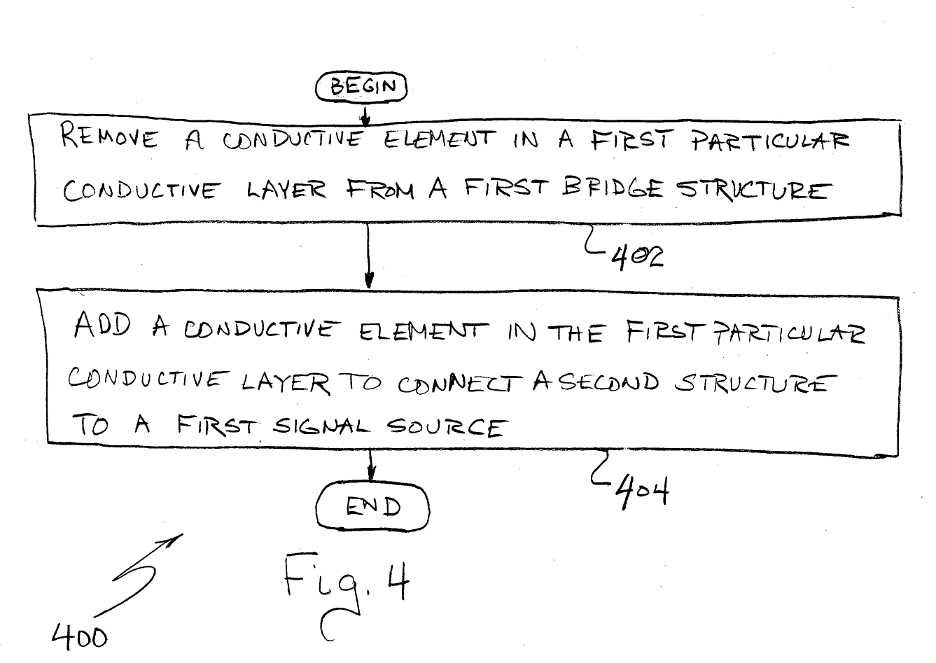

FIG. 4 is flow diagram of a method 400 for modifying the bit-cell 100 shown in FIG. 1A in accordance with some embodiments of the present invention. The method 400 includes removing a conductive element in a first particular conductive layer from a first bridge structure (block 402), and adding a conductive element in the first particular conductive layer to connect a second bridge structure to a first signal source (block 404).

In some embodiments of the method 400, removing the conductive element in the first particular conductive layer from the first bridge structure (block 402) includes removing the conductive element during fabrication of the first bridge structure by editing a metallization mask for the particular conductive layer.

In some embodiments of the method 400, adding the conductive element in the first particular conductive layer to connect the second bridge structure to the first signal source (block 404) includes adding the conductive element by editing the metallization mask.

In some embodiments of the method 400, the method 400 further includes removing a conductive element in a second particular conductive layer in the second bridge structure.

In some embodiments of the method 400, the method 400 further includes adding a conductive element in the second particular conductive layer to connect a third bridge structure to a second signal source.

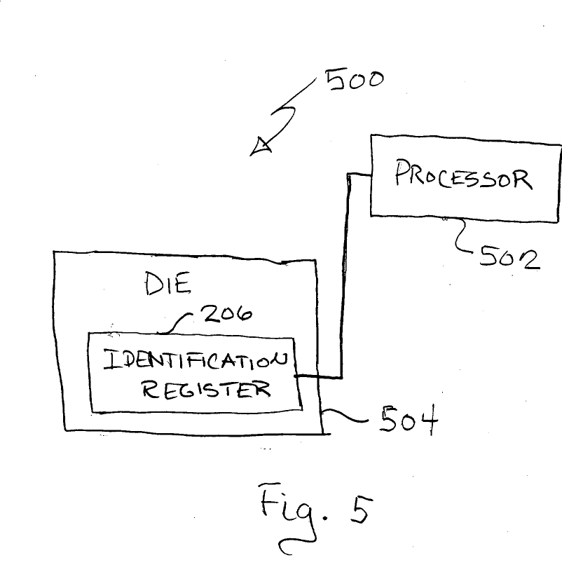

FIG. 5 is a block diagram of a computer system 500 including a processor 502 and a die 504 including an identification register 206, shown in FIG. 2, having a plurality of conductive bridge structures 102, shown in FIG. 1B. The identification register 206 is coupled to the processor 502. In some embodiments, the processor 502 comprises a microprocessor. In some embodiments, at least one of the plurality of conductive bridge structures 102 includes a conductive stack 140 (shown in FIG. 1D) having a gap.

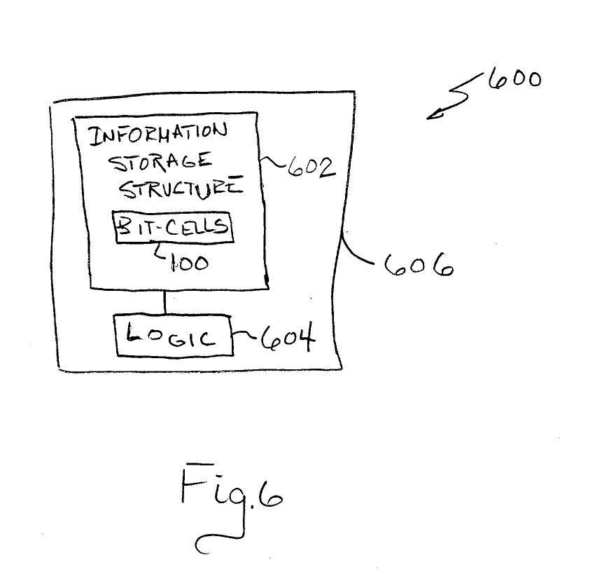

FIG. 6 is a block diagram of an apparatus 600 including an information storage structure 602 including one or more bit-cells 100, shown in FIG. 1A, and logic 604 formed on a substrate 606 in accordance with some embodiments of the present invention. The information storage structure 602 functions as a read-only-memory coupled to the logic 604 forming a processor core, a microcontroller, or a microprocessor. A read-only-memory can contain microcode instructions suitable for execution by the logic 604 or data for processing by the logic 604. When stored in the information storage structure 602, microcode instructions or data can be changed by editing a single metallization mask. Thus, if the logic 604 requires a change, for example, on metallization level three, and the microcode instructions or data also require a change, then the change to the microcode instructions or data can also be made by only changing metallization level three. Exemplary materials suitable for use in connection with the fabrication of the substrate 606 include semiconductors, such as silicon, germanium, or gallium arsenide.

Although specific embodiments have been described and illustrated herein, it will be appreciated by those skilled in the art, having the benefit of the present disclosure, that any arrangement which is intended to achieve the same purpose may be substituted for a specific embodiment shown. This application is intended to cover any adaptations or variations of the present invention. Therefore, it is intended that this invention be limited only by the claims and the equivalents thereof.

What is claimed is:

1. A bit-cell comprising:
a plurality of bridge structures; and
a driver including an input port and an output port, the input port connected to each of the plurality of bridge structures, wherein at most one of the plurality of bridge structures is connected to a signal source.

2. The bit-cell of claim 1, wherein each of the plurality of bridge structures includes a first conductive stack connected to a second conductive stack by a conductive beam.

3. The bit-cell of claim 2, wherein the conductive beam comprises a metal.

4. The bit-cell of claim 2, wherein the first conductive stack includes a gap on a particular layer.

5. The bit-cell of claim 4, wherein at least one of the plurality of bridge structures includes a connection on the particular layer to a signal source.

6. The bit-cell of claim 1, wherein the driver comprises an inverter.

7. The bit-cell of claim 1, wherein the signal source comprises a power source.

8. A communication system comprising:
a substrate;
a communication circuit formed on the substrate and coupled to an antenna; and
an identification register formed on the substrate and including a plurality of bit-cells, wherein each of the plurality of bit-cells can be changed during manufacturing of the communication circuit by changing only one metallization mask.

9. The communication system of claim 8, wherein at least one of the plurality of bit-cells comprises:
a plurality of bridge structures formed on the substrate; and
a driver formed on the substrate, the driver including an input port and an output port, the input port connected to each of the plurality of bridge structures, wherein at most one of the plurality of bridge structures is connected to a signal source.

10. The communication system of claim 9, wherein the substrate comprises a semiconductor.

11. The communication system of claim 10, wherein each of the plurality of bridge structures includes a first conductive stack connected to a second conductive stack by a conductive beam.

12. The communication system of claim 11, wherein the first conductive stack includes a plurality of conductive elements.

13. The communication system of claim 12, wherein each of the plurality of conductive elements is separated from adjacent conductive elements by a dielectric and connected to adjacent conductive elements by a via.

14. An interconnect comprising:
a first conductive bridge structure formed on a substrate, the first conductive bridge structure including each of a plurality of metallization layers included in an integrated circuit, the first conductive bridge structure having a proximal end and a distal end, and the first conductive bridge structure forming a conductive path between the proximal end and the distal end; and
a second conductive bridge structure formed on the substrate, the second conductive bridge structure including each of the plurality of metallization layers, the second conductive bridge structure having a proximal end and a distal end, the proximal end of the first bridge structure connected to the proximal end of the second bridge structure, the second conductive bridge structure forming a conductive path between the proximal end of the second bridge structure and the distal end of the second bridge structure, and the distal end and of the first conductive bridge structure and the distal end of the second bridge structure being unconnected.

15. The interconnect of claim 14, further comprising a signal source connected to the distal end of the first bridge structure.

16. The interconnect of claim 15, wherein the signal source comprises a logic signal.

17. The interconnect of claim 14, wherein the distal end of the second conductive bridge structure is adjacent to a first power source contact.

18. The interconnect of claim 17, wherein the first power source contact comprises a conductive stack.

19. A method comprising:
removing a conductive element in a first particular conductive layer from a first bridge structure; and
adding a conductive element in the first particular conductive layer to connect a second bridge structure to a first signal source.

20. The method of claim 19, wherein removing the conductive element in the first particular conductive layer from the first bridge structure comprises removing the conductive element during fabrication of the first bridge structure by editing a metallization mask for the particular conductive layer.

21. The method of claim 20, wherein adding the conductive element in the first particular conductive layer to connect the second bridge structure to the first signal source comprises adding the conductive element by editing the metallization mask.

22. The method of claim 21, further comprising removing a conductive element in a second particular conductive layer in the second bridge structure.

23. The method of claim 22, further comprising adding a conductive element in the second particular conductive layer to connect a third bridge structure to a second signal source.

24. A computer system comprising:
a processor;
a die including an identification register having a plurality conductive bridge structures, the identification register coupled to the processor.

25. The computer system of claim 24, wherein the processor comprises a microprocessor.

26. The computer system of claim 25, wherein at least one of the plurality of conductive bridge structures includes a conductive stack having a gap.

27. A method comprising:
providing an identification register on a die including a circuit having a plurality of metallization layers; and
changing only one metallization mask to modify the circuit and the identification register.

28. The method of claim 27, wherein providing the identification register on the die including the circuit comprises providing a bit-cell including a plurality of conductive bridge structures.

29. The method of claim 27, wherein providing the identification register on the die including the circuit comprises providing a plurality of bit-cells, each of the plurality of bit-cells including a plurality of conductive bridge structures.

30. An apparatus comprising:
logic formed on a die; and
an information storage structure coupled to the logic, the information storage structure including one or more bit-cells, each of the one or more bit-cells including a plurality of conductive bridge structures.

31. The apparatus of claim 30, wherein the information storage structure includes one or more microcode instructions.

32. The apparatus of claim 30, wherein the logic comprises a processor.
